(19) United States
(12) Patent Application Publication
(10) Pub. No.: US 2026/0150518 A1
(43) Pub. Date: May 28, 2026

(54) DISPLAY PANEL AND MANUFACTURING METHOD THEREFOR, AND DISPLAY DEVICE

(71) Applicants: Mianyang HKC Optoelectronics Technology Co.,Ltd., MIANYANG (CN); HKC CORPORATION LIMITED, SHENZHEN (CN)

(72) Inventors: Min HUANG, MIANYANG (CN); Jiajin LIU, MIANYANG (CN); Guoping YANG, MIANYANG (CN); Zhongbo ZHU, MIANYANG (CN); Lidan YE, MIANYANG (CN)

(73) Assignees: Mianyang HKC Optoelectronics Technology Co.,Ltd., MIANYANG (CN); HKC CORPORATION LIMITED, SHENZHEN (CN)

(21) Appl. No.: 19/383,663

(22) Filed: Nov. 9, 2025

(30) Foreign Application Priority Data
Nov. 28, 2024 (CN) 202411730461.4

(51) Int. Cl. H10K 59/122; H10K 59/12

(52) U.S. Cl. CPC H10K 59/122; H10K 59/1201

(57) ABSTRACT

A display panel and manufacturing method therefor, and display device are provided. The display panel includes a substrate; a driver substrate, disposed on the substrate; a pixel definition layer, disposed on the driver substrate, protruding from the driver substrate and defining a pixel accommodation region; a sub-pixel, disposed in the pixel accommodation region, wherein the sub-pixel may include an anode, an organic light-emitting layer and a cathode sequentially stacked in a direction from a position close to the driver substrate to a position away from the driver substrate; and an overhang structure, disposed on the pixel definition layer and protruding from the pixel accommodation region, wherein the overhang structure may include a transparent conductive layer and a transparent dielectric layer covering the transparent conductive layer, and the transparent conductive layer is disposed in contact with the cathode.

### CROSS REFERENCE TO RELATED APPLICATIONS

This application claims priority to China Patent Applicant No. 202411730461.4, filed on Nov. 28, 2024, in the National Intellectual Property Administration of China, the contents of which are herein incorporated by reference in their entireties.

### TECHNICAL FIELD

Embodiments of the present disclosure relate to the field of display technologies, in particular, to a display panel, a method for manufacturing a display panel, and a display device.

### BACKGROUND

Active-matrix organic light-emitting diode (AMOLED) display has become a currently mainstream display technology. In order to improve the resolution and reduce the cost, in the manufacturing process of the AMOLED, a mode of patterning the pixel by maskless deposition and photolithography can greatly increase the effective light emitting area (aperture ratio) of the AMOLED, which is beneficial to greatly increasing the pixel density. In order to achieve high resolution and colorization of the AMOLED, a cathode isolation column structure is introduced, that is, a metal mask is not used in device preparation, but before the organic thin film and the metal cathode are evaporated, an insulating partition wall is manufactured on the substrate, and finally different pixels of the device are separated to realize pixel array arrangement. This cathode isolation column structure is also referred to as an overhang structure.

In the related art, since the height of the overhang structure is higher than the height of the organic light-emitting layer of the pixel, part of the light emitted by the organic light-emitting layer is blocked or absorbed by the overhang structure surrounding the pixel, resulting in a loss of a part of the emergent light, which reduces the light extraction efficiency of the display panel and affects the display brightness of the display panel.

### SUMMARY OF THE DISCLOSURE

Some embodiments of the present disclosure may provide a display panel, a method for manufacturing a display panel, and a display device.

In a first aspect, some embodiments of the present disclosure may provide a display panel. The display panel may include a substrate; a driver substrate, disposed on the substrate; a pixel definition layer, disposed on the driver substrate, protruding from the driver substrate and defining a pixel accommodation region; a sub-pixel, disposed in the pixel accommodation region, wherein the sub-pixel may include an anode, an organic light-emitting layer and a cathode sequentially stacked in a direction from a position close to the driver substrate to a position away from the driver substrate; and an overhang structure, disposed on the pixel definition layer and protruding from the pixel accommodation region, wherein the overhang structure may include a transparent conductive layer and a transparent dielectric layer covering the transparent conductive layer, and the transparent conductive layer is disposed in contact with the cathode.

In a second aspect, some embodiments of the present disclosure may further provide a display device. The display device may include a display panel, including: a substrate; a driver substrate, disposed on the substrate; a pixel definition layer, disposed on the driver substrate, protruding from the driver substrate and defining a pixel accommodation region; a sub-pixel, disposed in the pixel accommodation region, wherein the sub-pixel comprises an anode, an organic light-emitting layer and a cathode sequentially stacked in a direction from a position close to the driver substrate to a position away from the driver substrate; and an overhang structure, disposed on the pixel definition layer and protruding from the pixel accommodation region, wherein the overhang structure comprises a transparent conductive layer and a transparent dielectric layer covering the transparent conductive layer, and the transparent conductive layer is disposed in contact with the cathode.

In a third aspect, some embodiments of the present disclosure may further provide a method for manufacturing a display panel, including: providing a preform, wherein the preform may include a substrate, a driver substrate, a pixel definition layer and an anode, the pixel definition layer protrudes from the drive substrate to define a pixel accommodation region, and the anode is disposed in the pixel accommodation region; depositing a transparent conductive material on the pixel definition layer and patterning the transparent conductive material to form a transparent conductive layer; depositing a transparent dielectric material on the transparent conductive layer and patterning the transparent dielectric material to form a transparent dielectric layer, and enabling the transparent dielectric layer to cover the transparent conductive layer to form an overhang structure; and sequentially evaporating and depositing an organic light-emitting material and a cathode conductive material on a side of the anode away from the driver substrate to form an organic light-emitting layer and a cathode, and enabling the cathode to be in contact with the transparent conductive layer.

### BRIEF DESCRIPTION OF THE DRAWINGS

FIG. 1 is a structural schematic view of a display panel in some embodiments of the present disclosure.

FIG. 2 is a structural schematic view of a display device in some other embodiments of the present disclosure.

FIG. 3 is a flowchart of a method for manufacturing a display panel in some embodiments of the present disclosure.

FIG. 4 is a structural schematic view corresponding to operation S1.

FIG. 5a is a structural schematic view corresponding to operation S21.

FIG. 5b is a structural schematic view corresponding to operation S22.

FIG. 6a is a structural schematic view corresponding to operation S31.

FIG. 6b is a structural schematic view corresponding to operation S32.

FIG. 7 is a structural schematic view corresponding to operation S4.

### DETAILED DESCRIPTION

The technical solutions in some embodiments of the present disclosure will be clearly and completely described below in conjunction with the accompanying drawings in some embodiments of the present disclosure. Obviously, the described embodiments are only some, rather than all, of the embodiments of the present disclosure. All other embodiments by a person of ordinary skills in the art based on embodiments of the present disclosure without creative efforts should all be within the protection scope of the present disclosure.

The terms “first”, “second”, and “third” in the present disclosure are only for the purpose of description, and should not be construed as indicating or implying relative importance or implicitly indicating the number of technical features referred to. Therefore, the features defined with “first”, “second”, and “third” may explicitly or implicitly include at least one of the features. In the description of the present disclosure, “a plurality of” means at least two, such as two, three, etc., unless otherwise specifically defined. All directional indicators (such as up, down, left, right, front, back . . . ) in embodiments of the present disclosure are only used to explain a motion state, a relative positional relationship between the components in a specific posture (as illustrated in the drawings). If the specific posture changes, then the directional indication will change accordingly. In addition, the terms “include”, “comprise” and any variations thereof are intended to cover non-exclusive inclusion. For example, a process, a method, a system, a product, or a device that includes a series of operations or units is not limited to the listed operations or units, but optionally includes unlisted operations or units, or optionally also includes other operations or units inherent to these processes, methods, products or devices.

Reference to “embodiment” herein means that a specific feature, structure, or characteristic described in conjunction with the embodiments may be included in at least one embodiment of the present disclosure. The appearance of this phrase in various locations in the specification does not necessarily refer to the same embodiment, nor is it an independent or alternative embodiment mutually exclusive with other embodiments. Those skilled in the art may explicitly and implicitly understand that, the embodiments described herein may be combined with other embodiments.

The present disclosure will be described in detail below with reference to the accompanying drawings and embodiments.

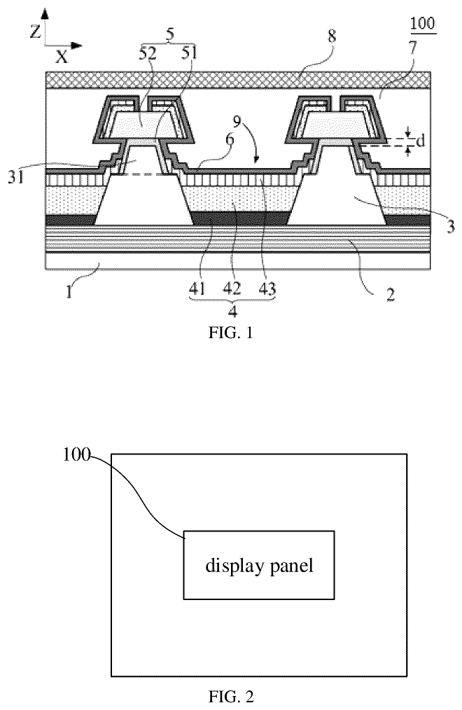

Referring to FIG. 1, FIG. 1 is a structural schematic view of a display panel in some embodiments of the present disclosure; The display panel 100 provided by the present application may be an organic light-emitting diode (OLED) display panel. The display panel 100 may include a substrate 1, a driver substrate 2, a pixel definition layer 3, a sub-pixel 4, and an overhang structure 5.

The substrate 1 is configured to support and protect each film layer structure of the display panel 100; in some embodiments, the substrate 1 may be a glass substrate. The driver substrate 2 may include a driving circuit layer (not shown) for driving the sub-pixels 4 to emit light, and the pixel definition layer 3 is disposed on a side surface of the driver substrate 2 away from the substrate 1. The pixel definition layer 3 protrudes from the driver substrate 2 and defines a plurality of pixel accommodating regions 9 for accommodating the sub-pixels 4.

The sub-pixel 4 is disposed in the pixel accommodating region 9, and the sub-pixel 4 may include an anode 41, an organic light-emitting layer 42, and a cathode 43 sequentially stacked in a direction from a position close to the driver substrate 2 to a position away from the driver substrate 2, wherein the anode 41 is in communication with the anode power line, and the cathode 43 is in communication with the cathode power line, so that the organic light-emitting layer 42 emits light after being conductive.

The overhang structure 5 is disposed on a side surface of the pixel definition layer 3 facing away from the driver substrate 2, and the overhang structure 5 protrudes and is disposed around the pixel accommodation region 9, to be configured to separate the sub-pixels 4 of different colors, thereby avoiding the problem of pixel crosstalk. Specifically, the overhang structure 5 may include a transparent conductive layer 51 and a transparent dielectric layer 52 sequentially stacked in a direction from a position close to the pixel definition layer 3 to a position away from the pixel definition layer 3.

The transparent conductive layer 51 is disposed on a side of the overhang structure 5 close to the pixel definition layer 3, and is located on a surface of the pixel definition layer 3 facing the overhang structure 5; and the transparent conductive layer 51 is in contact with the cathode 43 of the sub-pixel 4, so as to act as a common cathode and conduct with the cathodes 43 of different sub-pixels 4. The transparent dielectric layer 52 is disposed on a side surface of the transparent conductive layer 51 facing away from the pixel definition layer 3, and is configured to separate the sub-pixels 4 of different colors. Further, two side edges of the transparent dielectric layer 52 protrude from the transparent conductive layer 51 to form an eave structure, so that when depositing the organic light-emitting layer 42 and the cathode 43, the evaporation angle can be changed through the eave structure, so that the cathode 43 covers the organic light-emitting layer 42.

Specifically, at least part of the light emitted by the organic light-emitting layer 42 can transmit through the transparent conductive layer 51 and the transparent dielectric layer 52; In this way, by using the transparent conductive layer 51 and the transparent dielectric layer 52 to form the overhang structure 5, emergent light originally shielded or absorbed by the overhang structure 5 in the related art can transmit through the overhang structure 5, which effectively reducing the loss of emergent light, improving the light extraction efficiency of the display panel 100, and reducing the driving current required by the display panel 100 emitting light with the same brightness, thereby reducing the use energy consumption of the display panel 100 and effectively prolonging the service life.

In a specific embodiment, the transparent conductive layer 51 may include a transparent conductive oxide to implement a conductive function while transmitting light. Specifically, the transparent conductive oxide may include indium-tin oxide (ITO), aluminum-doped zinc oxide (AZO), gallium-doped zinc oxide (GZO), or tin-fluorine oxide (FTO). The transparent conductive oxide may be indium-tin oxide, and the transparent conductive layer 51 may be an ITO metal layer. The light transmittance of the transparent conductive layer 51 may be greater than or equal to 90%, so as to reduce the shielding or absorption of the transparent conductive layer 51 on the emergent light and reduce the loss of emergent light. Specifically, the light transmittance of the transparent conductive layer 51 may be any of 90%, 92%, 94%, 95%, or 96%. The light transmittance of the transparent conductive layer 51 may be greater than or equal to 95%.

In a specific embodiment, the transparent dielectric layer 52 may include a photoresist, which facilitates the exposure and etching after depositing the photoresist material to form the transparent dielectric layer 52. The photoresist may include one or more of a photo-olefin monomer photoresist, a diazoquinone-novolac photoresist or a polyvinyl alcohol laurate photoresist, so that the formed transparent dielectric layer 52 has good light-transmitting performance. Specifically, the light transmittance of the transparent dielectric layer 52 is greater than or equal to 80%, so as to reduce the shielding of the transparent dielectric layer 52 on the emergent light, and further reduce the loss of the emergent light. Specifically, the light transmittance of the transparent dielectric layer 52 may be any one of 80%, 83%, 85%, 90%, or 95%.

Referring to FIG. 1, in a specific embodiment, the side of the pixel definition layer 3 facing the overhang structure 5 is further provided with a protrusion 31 to support the overhang structure 5 so that the overhang structure 5 has a sufficient height that when the organic light-emitting layer 42 and the cathode 43 are deposited by evaporation, the evaporation angle can be changed by means of the eave structure so that the cathode 43 covers the organic light emitting layer 42.The projection of the protrusion 31 on the substrate 1 along a stacking direction Z of the display panel 100 is located in the projection of the transparent dielectric layer 52 on the substrate 1 in the stacking direction Z, so that the transparent dielectric layer 52 can shield the transparent conductive layer 51 disposed on the protrusion 31 to form the eave structure.

The transparent conductive layer 51 is disposed between the transparent dielectric layer 52 and the protrusion 31, and the projection of the transparent conductive layer 51 on the substrate 1 in the stacking direction Z is located in the projection of the transparent dielectric layer 52 on the substrate 1 in the stacking direction Z, so that the transparent dielectric layer 52 can cover the transparent conductive layer 51 to form the eave structure. Specifically, the transparent conductive layer 51 at least covers a portion of the surface of the protrusion 31 along the side walls of the two sides of a first direction X, so that the cathode 43 of the sub-pixel 4 can be in lap joint with the transparent conductive layer 51, thereby realizing the electrical connection between the cathode 43 and the transparent conductive layer 51, wherein the first direction X is substantially perpendicular to the stacking direction Z.

It can be understood that although the transparent conductive layer 51 has a relatively high light transmittance, but also inevitably absorbs and reflects a small amount of emergent light, the thickness d of the transparent conductive layer 51 can be set to be smaller by arranging the protrusion 31 to support the height of the overhang structure 5, thereby reducing the absorption and reflection of the transparent conductive layer 51 to the emergent light, and further reducing the loss of emergent light. Reducing the thickness of the transparent conductive layer 51 can also simplify the manufacturing process. Specifically, the thickness d of the transparent conductive layer 51 may be greater than or equal to 20 nm and less than or equal to 100 nm, so as to reduce the absorption and reflection of the transparent conductive layer 51 to the emergent light and ensure the conductive function of the transparent conductive layer 51; specifically, the thickness d of the transparent conductive layer 51 may be any value in 20 nm, 40 nm, 60 nm, 80 nm, or 100 nm.

Further, the light transmittance of the pixel definition layer 3 may be greater than or equal to 85%, so as to reduce the shielding of the emergent light by the protrusion 31, so that the emergent light can transmit through the protrusion 31 to further reduce the loss of the emergent light. Specifically, the light transmittance of the pixel definition layer 3 may be any one of 85%, 87%, 90%, 95%, or 98%.

Further, the refractive index of the pixel definition layer 3 may be greater than or equal to 1.4 and less than or equal to 1.7, so that the emergent light is emitted after being refracted by the protrusion 31 of the pixel definition layer 3, so as to increase the visual angle range of the display panel 100. Specifically, the refractive index of the pixel definition layer 3 may be any of 1.4, 1.5, 1.6, or 1.7. Specifically, the pixel definition layer 3 may include at least one of polyimide or polycarbonate.

As shown in FIG. 1, in a specific embodiment, the anode 41 is disposed on a side surface of the driver substrate 2 facing the pixel definition layer 3, located in the pixel accommodation region 9, and etched into a preset pattern. The pixel definition layer 3 is disposed between the anodes 41 of the adjacent sub-pixels 4 to space the anodes 41 between the sub-pixels 4 to prevent the anodes 41 of the adjacent sub-pixels 4 from being conducted to affect the display effect of the display panel 100. Specifically, the height of the pixel definition layer 3 in the stacking direction Z may also be greater than the height of the anode 41 in the stacking direction Z, so as to further ensure that the anode 41 of the sub-pixel 4 cannot be turned on; the two sides of the pixel definition layer 3 may also cover a part of the anode 41.

The organic light-emitting layer 42 is disposed on a side surface of the anode 41 facing away from the driver substrate 2. In a specific embodiment, the organic light-emitting layer 42 may be deposited on the display panel 100 by evaporation; and the organic light-emitting layer 42 covers the anode 41 and covers a part of the pixel definition layer 3, so as to completely cover the anode 41, thereby preventing the subsequent evaporation of the cathode 43 from being in contact with the anode 41 and affecting the display effect.

The cathode 43 is disposed on a side surface of the organic light-emitting layer 42 facing away from the anode 41. The cathode 43 may also be evaporated on the surface of the organic light-emitting layer 42 through a vapor deposition source. In the evaporation process, the cathode 43 can be overlapped on the metal layer of the transparent conductive layer 51 by changing the evaporation angle, so that the cathode 43 is in contact with the transparent conductive layer 51 that the cathode 43 of the sub-pixel 4 is conducts with the transparent conductive layer 51 that serves as a common cathode.

In a specific embodiment, the display panel 100 may further include an etching protective layer 6, a first encapsulation layer 7, and a second encapsulation layer 8, wherein the etching protective layer 6 is configured to perform anti-etching protection on the sub-pixel 4 in the process of manufacturing the sub-pixels 4 of other colors of the display panel 100, so as to prevent the prepared sub-pixel 4 from being damaged in a subsequent preparation process. Specifically, the etching protective layer 6 is disposed on a side of the cathode 43 facing away from the organic light-emitting layer 42 and covers a surface of the cathode 43, and one end of the etching protective layer 6 is lapped on the insulating layer of the transparent dielectric layer 52 to resist etching protection of each film layer of the sub-pixel 4. The etching protective layer 6 may include a non-conductive inorganic material; specifically, the etching protective layer 6 may include a silicon-containing inorganic material, for example, a SiNx inorganic material.

After the preparation of all the sub-pixels 4 is completed, the first encapsulation layer 7 and the second encapsulation layer 8 may be disposed on the display panel 100 to integrally encapsulate the display panel 100. Specifically, the first encapsulation layer 7 covers a side of the etching protective layer 6 facing away from the driver substrate 2; and the second encapsulation layer 8 covers a side of the first encapsulation layer 7 facing away from the driver substrate 2. The first encapsulation layer 7 may be an organic encapsulation layer, and the second encapsulation layer 8 may be an inorganic encapsulation layer.

An embodiment of the present disclosure provides a display panel 100, including a substrate 1, a driver substrate 2, a pixel definition layer 3, a sub-pixel 4, and an overhang structure 5; the driver substrate 2 is disposed on the substrate 1; the pixel definition layer 3 is disposed on the driver substrate 2; the pixel definition layer 3 protrudes from the drive substrate 2 and defines a pixel accommodation region 9; the sub-pixel 4 is disposed in the pixel accommodation region 9; the sub-pixel 4 may include an anode 41, an organic light-emitting layer 42 and a cathode 43 which are sequentially stacked in a direction from a position close to the driver substrate to a position away from the driver substrate; the overhang structure 5 is disposed on the pixel definition layer and protruding from the pixel accommodation region 9; the overhang structure 5 may include a transparent conductive layer 51 and a transparent dielectric layer 52 covering the transparent conductive layer 51; the transparent conductive layer 51 is electrically connected to the driver substrate 2; and the transparent conductive layer 51 is disposed in contact with the cathode 43. By using the transparent conductive layer and the transparent dielectric layer to form the overhung structure, the emergent light originally covered or absorbed by the overhung structure in the related art can transmit through the present overhung structure, which effectively reduces the loss of emergent light, improves the light extraction efficiency of the display panel 100, and reduces the driving current required by the display panel 100 emitting light with the same brightness, thereby reducing the use energy consumption of the display panel 100 and effectively prolonging the service life.

Referring to FIG. 2, FIG. 2 is a structural schematic view of a display device in some other embodiments of the present disclosure. The display device may include the display panel 100 according to any one of the above embodiments, which can effectively reduce the loss of emergent light, improve the light extraction efficiency of the display panel 100, reduce the driving current required by the display panel 100 to emit light with the same brightness, thereby reducing the use energy consumption of the display panel and effectively prolonging the service life.

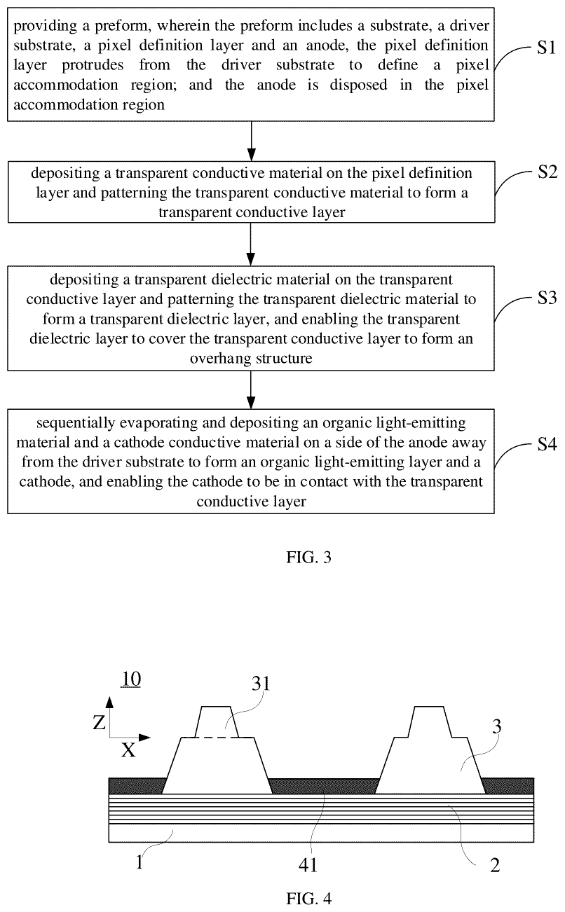

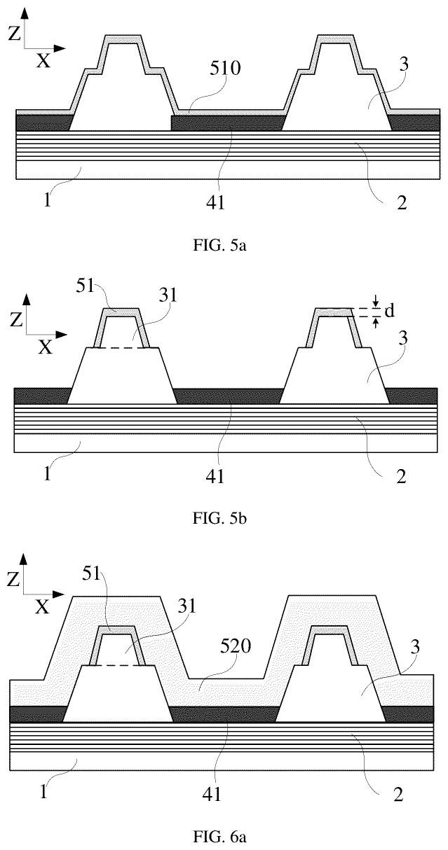

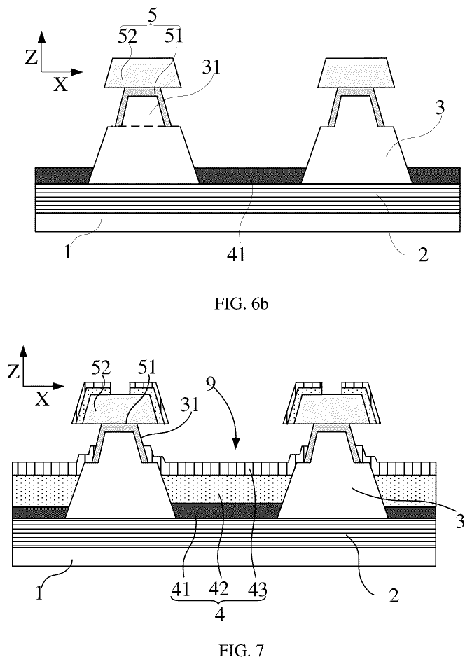

Referring to FIG. 3 to FIG. 7, F FIG. 3 is a flowchart of a method for manufacturing a display panel in some embodiments of the present disclosure. FIG. 4 is a structural schematic view corresponding to operation S1. FIG. 5a is a structural schematic view corresponding to operation S21. FIG. 5b is a structural schematic view corresponding to operation S22. FIG. 6a is a structural schematic view corresponding to operation S31. FIG. 6b is a structural schematic view corresponding to operation S32. FIG. 7 is a structural schematic view corresponding to operation S4. An embodiment of this application further provides a manufacturing method of a display panel, configured to prepare the display panel in any one of the aforesaid embodiments, and the operations of the method specifically include operation as follows.

At operation S1: providing a preform, wherein the preform includes a substrate, a driver substrate, a pixel definition layer and an anode, the pixel definition layer protrudes from the driver substrate to define a pixel accommodation region 9; and the anode is disposed in the pixel accommodation region 9.

Specifically, as shown in FIG. 4, a structure such as a driving circuit layer is manufactured on a surface of one side of the substrate 1 to form a driver substrate 2, then an anode conductive material is deposited on the surface of the side of the driver substrate 2 away from the substrate 1 and etched into a preset pattern to form an anode 41, and then a transparent dielectric material is deposited on the surface, not covered by the anode 41, of the driver substrate 2 to form a pixel definition layer 3, and an edge of the pixel definition layer 3 covers an edge of the anode 41. The height of the pixel definition layer 3 in the stacking direction Z is greater than the thickness of the anode 41 in the stacking direction Z, and the pixel definition layer 3 surrounds to define a plurality of openings, that is, the pixel accommodation region 9.

Specifically, the specific operations of forming the pixel definition layer 3 include operation as follows.

Operation S11: depositing the transparent dielectric material on a side of the driver substrate away from the substrate.

Specifically, the transparent dielectric material may be at least one of polyimide or polycarbonate, and the light transmittance of the formed pixel definition layer 3 is greater than or equal to 85%, so as to reduce the shielding of the emergent light by the protrusion 31, so that the emergent light can transmit through the protrusion 31 to further reduce the loss of the emergent light. Specifically, the light transmittance of the pixel definition layer 3 may be any of 85%, 87%, 90%, 95%, or 98%. The refractive index of the pixel definition layer 3 is greater than or equal to 1.4 and less than or equal to 1.7, so that the emergent light is refracted by the protrusion 31 of the pixel definition layer 3 and then is emitted to increase the visible angle range of the display panel 100; specifically, the refractive index of the pixel definition layer 3 may be any of 1.4, 1.5, 1.6, or 1.7. The transparent dielectric covers the surface of the anode 41 and the surface of the driver substrate 2 that is not covered by the anode 41.

Operation S12: using a semi-exposure process to etch the transparent dielectric material to form the pixel definition layer, wherein a side of the pixel definition layer away from the driver substrate has a protrusion.

In a specific implementation process, A halftone mask with partially transmissive region and clear region is used to expose and etch the transparent dielectric material to form the pixel definition layer 3 having the protrusion 31, wherein alignment of the halftone mask's clear region to anode 41 enables etching of the part of the transparent dielectric material over anode 41, and exposing the anode 41. The partially transparent dielectric material corresponding jointly to the opaque and partially transmissive region of the halftone mask forms a stepped pixel definition layer 3; wherein a part of the transparent dielectric material corresponding to the opaque area of the halftone mask forms the protrusion 31 for supporting the overhang structure 5 so that the overhang structure 5 has a sufficient height.

Operation S2: depositing a transparent conductive material on the pixel definition layer and patterning the transparent conductive material to form a transparent conductive layer.

In a specific implementation process, the operation S2 specifically includes operation as follows.

Operation S21: depositing a transparent conductive oxide material on the surface of the pixel definition layer and the surface of the anode to form a conductive oxide layer.

Specifically, as shown in FIG. 5a, at least one of conductive oxides such as indium-tin oxide, aluminum-doped zinc oxide, gallium-doped zinc oxide, and fluorine-doped tin oxide is deposited on the surface of the side of the pixel definition layer 3 away from the driver substrate 2 and the surface of the anode 41 away from the driver substrate 2 to form the conductive oxide layer 510, wherein the thickness d of the conductive oxide layer 510 is greater than or equal to 20 nm and less than or equal to 100 nm, and specifically, the thickness d of the conductive oxide layer 510 may be any value in 20 nm, 40 nm, 60 nm, 80 nm, or 100 nm.

Operation S22: patterning the conductive oxide layer in an exposure etching manner to form the transparent conductive layer, and enabling the transparent conductive layer to at least cover some surfaces of sidewalls of the protrusion along two sides of a first direction, wherein the first direction is substantially perpendicular to the stacking direction.

Specifically, as shown in FIG. 5b, the conductive oxide layer 510 is exposed and etched by using the mask to remove the conductive oxide layer 510 on the surface of the anode 41 and the part of the conductive oxide layer 510 on the surface of the pixel definition layer 3, and the part of the conductive oxide layer 510 on the surface of the protrusion 31 is retained to form the transparent conductive layer 51. Specifically, the transparent conductive layer 51 at least covers a part of the surfaces of the side walls of the protrusion 31 along the first direction X, and a surface of the protrusion 31 away from the driver substrate 2, the thickness d of the transparent conductive layer 51 is greater than or equal to 20 nm and less than or equal to 100 nm, so as to reduce the absorption and reflection of the transparent conductive layer 51 to the emergent light and ensure the conductive function of the transparent conductive layer 51; specifically, the thickness d of the transparent conductive layer 51 may be any value in 20 nm, 40 nm, 60 nm, 80 nm, or 100 nm.

In operation S3, depositing a transparent dielectric material on the transparent conductive layer and patterning the transparent dielectric material to form a transparent dielectric layer, and enabling the transparent dielectric layer to cover the transparent conductive layer to form an overhang structure.

In a specific implementation process, operation S3 specifically includes the following operations S31 and S32.

Operation S31: depositing the transparent dielectric material on the surface of the transparent conductive layer, the surface of the pixel definition layer and the surface of the anode to form the transparent dielectric material layer.

Specifically, as shown in FIG. 6a, a surface of the transparent conductive layer 51 away from the pixel definition layer 3, a surface of the pixel definition layer 3 not covered by the transparent conductive layer 51, and a surface of the anode 41 away from the driver substrate 2 are deposited with at least one of a light-transmitting photoresist, such as a diazoquinone-novolac photoresist or a polyvinyl alcohol laurate photoresist, to form a transparent dielectric material layer 520.

Operation S32: patterning the transparent dielectric material layer in an exposure etching manner to form the transparent dielectric layer.

Specifically, as shown in FIG. 6b, the transparent dielectric material layer 520 is exposed and etched by using a mask to remove the transparent dielectric material layer 520 on the surface of the anode 41 and the surface of the pixel definition layer 3, and the transparent dielectric material layer 520 on the surface of the transparent conductive layer 51 located on the side wall of the protrusion 31; the part of the transparent dielectric material layer 520 corresponding to the end of the protrusion 31 away from the driver substrate 2 is reserved to form the transparent dielectric layer 52, and meanwhile, by controlling the exposure stripping condition, the transparent dielectric layer 52 can cover the transparent conductive layer 51 to form an eave structure; and when the organic light-emitting layer 42 and the cathode 43 are deposited by evaporation, the evaporation angle can be changed through the eave structure to enable the cathode 43 to cover the organic light-emitting layer 42.

Specifically, the transparent dielectric layer 52 and the transparent conductive layer 51 form an overhang structure 5; two ends of the transparent dielectric layer 52 in the first direction X protrude from the transparent conductive layer 51, and a projection of the transparent conductive layer 51 on the substrate 1 in the stacking direction Z is located in a projection of the transparent dielectric layer 52 in the stacking direction Z on the substrate 1.

Operation S4: sequentially evaporating and depositing an organic light-emitting material and a cathode conductive material on a side of the anode away from the driver substrate to form an organic light-emitting layer and a cathode, and enabling the cathode to be in contact with the transparent conductive layer.

In a specific implementation process, the organic light-emitting layer 42 may be deposited on the display panel 100 by evaporation and completely cover the anode 41; the cathode 43 may also be deposited on the surface of the organic light-emitting layer 42 by evaporation; the anode 41, the organic light-emitting layer 42, and the cathode 43 jointly form the sub-pixel 4.

Specifically, in the evaporation process, the evaporation angle can be changed through the eave structure formed by the transparent conductive layer 51 and the transparent dielectric layer 52, so that the cathode 43 completely covers the organic light-emitting layer 42 and at least covers part of the pixel definition layer 3, and meanwhile, the cathode 43 covers a part of the surface of the transparent conductive layer 51 to separate the organic light-emitting layer 42 from the transparent conductive layer 51.

As shown in FIG. 1, in a specific implementation process, after operation S4, the method may further include: depositing an inorganic material on a side surface of the cathode away from the organic light-emitting layer and a surface of the overhang structure to form an etching protective layer; and overlapping the etching protective layer with the overhang structure.

Specifically, the etching protective layer 6 covers part of the surface of the transparent dielectric layer 52 and is overlapped on the surface of the transparent dielectric layer 52 to protect the internal film layer structure.

In a specific implementation process, after the operation of forming the etching protective layer 6, the method may further include: sequentially depositing an organic material and an inorganic material on a side of the etching protective layer away from the cathode to form a first encapsulation layer and a second encapsulation layer.

Specifically, an organic material is deposited on the surface of the etching protective layer 6 away from the driver substrate 2 and the surface of the transparent dielectric layer 52 which is not covered to form the first encapsulation layer 7, and the surface of the side of the first encapsulation layer 7 away from the driver substrate 2 is planarized; and then an inorganic material is deposited on the surface of the side of the first encapsulation layer 7 away from the driver substrate 2 to form the second encapsulation layer 8, so as to form the display panel 100 as shown in FIG. 1.

An embodiment of the present application provides a method for manufacturing a display panel 100, by providing a preform 10; The preform 10 includes a substrate 1, a driver substrate 2, a pixel definition layer 3, and an anode 41; the pixel definition layer 3 protrudes from the driver substrate 2 to define a pixel accommodation region 9; the anode 41 is disposed in the pixel accommodation region 9; then depositing a transparent conductive material on the pixel definition layer and patterning the transparent conductive material to form a transparent conductive layer; and depositing a transparent dielectric material on the transparent conductive layer and patterning the transparent dielectric material to form a transparent dielectric layer, and enabling the transparent dielectric layer to cover the transparent conductive layer to form an overhang structure; and finally sequentially evaporating and depositing an organic light-emitting material and a cathode conductive material on a side of the anode away from the driver substrate to form an organic light-emitting layer and a cathode, and enabling the cathode to be in contact with the transparent conductive layer. In this way, by using the transparent conductive layer and the transparent dielectric layer to form the overhung structure, the emergent light originally covered or absorbed by the overhung structure in the related art can transmit through the present overhung structure, which effectively reduces the loss of emergent light, improves the light extraction efficiency of the display panel 100, and reduces the driving current required by the display panel 100 emitting light with the same brightness, thereby reducing the use energy consumption of the display panel 100 and effectively prolonging the service life.

The above are only implementations of the present disclosure, and do not limit the patent scope of the present disclosure. Any equivalent changes to the structure or processes made by the description and drawings of this application or directly or indirectly used in other related technical field are included in the protection scope of the present disclosure.

1. A display panel, comprising:
a substrate;
a driver substrate, disposed on the substrate;
a pixel definition layer, disposed on the driver substrate, protruding from the driver substrate and defining a pixel accommodation region;
a sub-pixel, disposed in the pixel accommodation region, wherein the sub-pixel comprises an anode, an organic light-emitting layer and a cathode sequentially stacked in a direction from a position close to the driver substrate to a position away from the driver substrate; and
an overhang structure, disposed on the pixel definition layer and protruding from the pixel accommodation region, wherein the overhang structure comprises a transparent conductive layer and a transparent dielectric layer covering the transparent conductive layer, and the transparent conductive layer is disposed in contact with the cathode.

2. The display panel as claimed in claim 1, wherein the transparent dielectric layer comprises a photoresist, and the photoresist comprises one or more of a photo-olefin monomer photoresist, a diazoquinone-novolac photoresist or a polyvinyl alcohol laurate photoresist;
the transparent conductive layer comprises a transparent conductive oxide, and the transparent conductive oxide comprises indium tin oxide.

3. The display panel as claimed in claim 2, wherein the light transmittance of the transparent conductive layer is greater than or equal to 90%.

4. The display panel as claimed in claim 2, wherein the light transmittance of the transparent dielectric layer is greater than or equal to 80%.

5. The display panel as claimed in claim 1, wherein a side of the pixel definition layer facing the overhang structure has a protrusion for supporting the overhang structure; and a projection of the protrusion on the substrate along a stacking direction of the display panel is located in a projection of the transparent dielectric layer on the substrate in the stacking direction;
the transparent conductive layer is disposed between the transparent dielectric layer and the protrusion, and the transparent conductive layer at least covers a portion of surfaces of sidewalls of the protrusion along a first direction, wherein the first direction is substantially perpendicular to the stacking direction.

6. The display panel as claimed in claim 5, wherein a thickness of the transparent conductive layer is greater than or equal to 20 nm and less than or equal to 100 nm.

7. The display panel as claimed in claim 5, wherein a light transmittance of the pixel definition layer is greater than or equal to 85%, and a refractive index of the pixel definition layer is greater than or equal to 1.4 and less than or equal to 1.7.

8. The display panel as claimed in claim 7, wherein the pixel definition layer comprises at least one of polyimide or polycarbonate.

9. A display device, comprising:
a display panel, comprising:
a substrate;
a driver substrate, disposed on the substrate;
a pixel definition layer, disposed on the driver substrate, protruding from the driver substrate and defining a pixel accommodation region;
a sub-pixel, disposed in the pixel accommodation region, wherein the sub-pixel comprises an anode, an organic light-emitting layer and a cathode sequentially stacked in a direction from a position close to the driver substrate to a position away from the driver substrate; and
an overhang structure, disposed on the pixel definition layer and protruding from the pixel accommodation region, wherein the overhang structure comprises a transparent conductive layer and a transparent dielectric layer covering the transparent conductive layer, and the transparent conductive layer is disposed in contact with the cathode.

10. The display device as claimed in claim 9, wherein the transparent dielectric layer comprises a photoresist, and the photoresist comprises one or more of a photo-olefin monomer photoresist, a diazoquinone-novolac photoresist or a polyvinyl alcohol laurate photoresist;
the transparent conductive layer comprises a transparent conductive oxide, and the transparent conductive oxide comprises indium tin oxide.

11. The display device as claimed in claim 10, wherein the light transmittance of the transparent conductive layer is greater than or equal to 90%, and the light transmittance of the transparent dielectric layer is greater than or equal to 80%.

12. The display device as claimed in claim 9, wherein a side of the pixel definition layer facing the overhang structure has a protrusion for supporting the overhang structure; and a projection of the protrusion on the substrate along a stacking direction of the display panel is located in a projection of the transparent dielectric layer on the substrate in the stacking direction;
the transparent conductive layer is disposed between the transparent dielectric layer and the protrusion, and the transparent conductive layer at least covers a portion of surfaces of sidewalls of the protrusion along a first direction, wherein the first direction is substantially perpendicular to the stacking direction.

13. The display device as claimed in claim 12, wherein a thickness of the transparent conductive layer is greater than or equal to 20 nm and less than or equal to 100 nm.

14. The display device as claimed in claim 12, wherein a light transmittance of the pixel definition layer is greater than or equal to 85%, and a refractive index of the pixel definition layer is greater than or equal to 1.4 and less than or equal to 1.7.

15. The display device as claimed in claim 14, wherein the pixel definition layer comprises at least one of polyimide or polycarbonate.

16. A method for manufacturing a display panel, comprising:
providing a preform, wherein the preform comprises a substrate, a driver substrate, a pixel definition layer and an anode, the pixel definition layer protrudes from the drive substrate to define a pixel accommodation region, and the anode is disposed in the pixel accommodation region;
depositing a transparent conductive material on the pixel definition layer and patterning the transparent conductive material to form a transparent conductive layer;
depositing a transparent dielectric material on the transparent conductive layer and patterning the transparent dielectric material to form a transparent dielectric layer, and enabling the transparent dielectric layer to cover the transparent conductive layer to form an overhang structure; and
sequentially evaporating and depositing an organic light-emitting material and a cathode conductive material on a side of the anode away from the driver substrate to form an organic light-emitting layer and a cathode, and enabling the cathode to be in contact with the transparent conductive layer.

17. The method for manufacturing the display panel as claimed in claim 16, wherein a side of the pixel definition layer away from the driver substrate comprises a protrusion, and the operation of depositing a transparent conductive material on the pixel definition layer and patterning the transparent conductive material to form a transparent conductive layer comprises:
depositing a transparent conductive oxide material on the surface of the pixel definition layer and the surface of the anode to form a conductive oxide layer; and
patterning the conductive oxide layer in an exposure etching manner to form the transparent conductive layer, and enabling the transparent conductive layer to at least cover some surfaces of sidewalls of the protrusion along two sides of a first direction, wherein the first direction is substantially perpendicular to a stacking direction.

18. The method for manufacturing the display panel as claimed in claim 16, further comprising:
depositing the transparent dielectric material on a side of the driver substrate away from the substrate;
using a semi-exposure process to etch the transparent dielectric material to form the pixel definition layer, wherein a side of the pixel definition layer away from the driver substrate has a protrusion.

19. The method for manufacturing the display panel as claimed in claim 16, the operation of depositing a transparent dielectric material on the transparent conductive layer and patterning the transparent dielectric material to form a transparent dielectric layer, and enabling the transparent dielectric layer to cover the transparent conductive layer to form an overhang structure comprising:
depositing the transparent dielectric material on the surface of the transparent conductive layer, the surface of the pixel definition layer and the surface of the anode to form the transparent dielectric material layer;
patterning the transparent dielectric material layer in an exposure etching manner to form the transparent dielectric layer.

20. The method for manufacturing the display panel as claimed in claim 16, after the operation of sequentially evaporating and depositing an organic light-emitting material and a cathode conductive material on a side of the anode away from the driver substrate to form an organic light-emitting layer and a cathode, and enabling the cathode to be in contact with the transparent conductive layer, further comprising:
depositing an inorganic material on a side surface of the cathode away from the organic light-emitting layer and a surface of the overhang structure to form an etching protective layer; and overlapping the etching protective layer with the overhang structure;
sequentially depositing an organic material and an inorganic material on a side of the etching protective layer away from the cathode to form a first encapsulation layer and a second encapsulation layer.
